(19) United States
(12) Patent Application Publication
(10) Pub. No.: US 2023/0094306 A1
(43) Pub. Date: Mar. 30, 2023

(54) DISPLAY DEVICE AND METHOD OF MANUFACTURING THE SAME

(71) Applicant: Samsung Display Co., LTD., Yongin-si, Gyeonggi-do (KR)

(72) Inventors: Jun Hyeong PARK, Seoul (KR); Kyung Min KIM, Hwaseong-si (KR); Dong Won KIM, Seoul (KR); Ji Yeon SEO, Hwaseong-si (KR)

(21) Appl. No.: 17/948,087

(22) Filed: Sep. 19, 2022

(30) Foreign Application Priority Data
Sep. 24, 2021 (KR) 10-2021-0126046

(51) Int. Cl. H01L 27/32; H01L 51/56

(52) U.S. Cl. CPC H01L 27/3258; H01L 27/3246; H01L 51/56; H01L 2227/323

(57) ABSTRACT

A display device and a method of manufacturing the same are provided. The display device comprises a substrate having a base and a protruding pattern protruding from the base; a first planarization layer on the protruding pattern and comprising a first surface, a second surface, and side surfaces connecting the first surface and the second surface; and a dam structure on the first planarization layer and comprises a first sub-dam and a second sub-dam, wherein a first angle formed by the second surface of the first planarization layer and each side surface of the first planarization layer is in a range of 30 to 60 degrees.

### CROSS-REFERENCE TO RELATED APPLICATION

The present application claims priority to and the benefit of Korean Patent Application No. 10-2021-0126046, filed on Sep. 24, 2021, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As the information society develops, consumer demand for display devices for displaying images has increased over time, and display devices are more and more often incorporated into various electronic devices. For example, display devices may be applied or incorporated into various electronic devices such as smartphones, digital cameras, notebook computers, navigation devices, and smart televisions.

As display devices, various types of display devices such as a liquid crystal display device and an organic light emitting display device may be used. Among them, the organic light emitting display device displays an image using an organic light emitting element that generates light through recombination of electrons and holes. The organic light emitting display device includes a plurality of transistors that provide a driving current to the organic light emitting element.

As display devices are applied to various electronic devices, display devices having various designs may be utilized, depending on the design and application of the electronic device. For example, a display device may display images not only on a front part but also on bending parts respectively bent from four edges of the front part and a corner part located between the bending parts.

The above information disclosed in this Background section is only for enhancement of understanding of the background and therefore the information discussed in this Background section does not necessarily constitute prior art.

### SUMMARY

Aspects of some embodiments of the present disclosure include a display device having relatively improved reliability.

However, aspects of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments of the present disclosure, a display device comprises a substrate which comprises a base and a protruding pattern protruding from the base; a first planarization layer which is on the protruding pattern and comprises a first surface, a second surface, and side surfaces connecting the first surface and the second surface; and a dam structure on the first planarization layer and comprises a first sub-dam and a second sub-dam, wherein a first angle formed by the second surface of the first planarization layer and each side surface of the first planarization layer is in the range of 30 to 60 degrees.

According to some embodiments of the present disclosure, a display device includes a substrate which comprises a base and a protruding pattern protruding from the base; a first planarization layer on the substrate and comprises a first surface, a second surface, and side surfaces connecting the first surface and the second surface; a plurality of first pixels on the base; and a plurality of second pixels on the protruding pattern, wherein a first angle formed by the second surface of the first planarization layer and each side surface of the first planarization layer is in the range of 30 to 60 degrees.

According to some embodiments of the present disclosure, a method of manufacturing a display device includes preparing a substrate, a first planarization layer on the substrate, a second planarization layer on the first planarization layer, a barrier material layer on the second planarization layer and exposing the second planarization layer in a first area, and a mask pattern on the barrier material layer and exposing the barrier material layer in a second area and a third area; and forming a cut part by etching the second planarization layer, the first planarization layer, and the substrate in the first area, wherein the second area exposes a first surface and side surfaces of the barrier material layer, and the third area exposes the first surface of the barrier material layer.

Further details of some embodiments according to the present disclosure are described below in the detailed description and are illustrated in the drawings.

According to some embodiments of the present disclosure, reliability of the display device may be improved.

The effects of embodiments according to the present disclosure are not limited to the aforementioned effects, and various other effects are included in the present specification.

### BRIEF DESCRIPTION OF THE DRAWINGS

These and/or other aspects will become more apparent and more readily appreciated from the following description of the embodiments, taken in conjunction with the accompanying drawings in which:

FIG. 1 is a perspective view of a display device according to some embodiments;

FIG. 2 is a plan view of the display device of FIG. 1 according to some embodiments;

FIG. 3 is a development drawing of a display panel of the display device according to some embodiments;

FIG. 4 is an enlarged view of area A of FIG. 3 according to some embodiments;

FIG. 5 is a partial perspective view of the display panel of the display device according to some embodiments;

FIG. 6 is an enlarged view of area B of FIG. 4 according to some embodiments;

FIG. 7 is a cross-sectional view taken along the line VII-VII′ of FIG. 6 according to some embodiments;

FIG. 8 is a cross-sectional view taken along the line VIII-VIII′ of FIG. 6 according to some embodiments;

FIG. 9 is an enlarged view of area C of FIG. 8 according to some embodiments;

FIG. 10 is a cross-sectional view taken along the line X-X′ of FIG. 6;

FIGS. 11 through 14 are cross-sectional views for explaining a method of manufacturing a display device according to some embodiments;

FIG. 15 is a cross-sectional view of a display device according to some embodiments;

FIG. 16 is an enlarged view of area D of FIG. 15 according to some embodiments;

FIG. 17 is a cross-sectional view of a display device according to some embodiments; and

FIG. 18 is an enlarged view of area E of FIG. 17 according to some embodiments.

### DETAILED DESCRIPTION

Further details of some embodiments of the present invention will now be described more fully hereinafter with reference to the accompanying drawings, in which aspects of some embodiments of the present invention are shown. The present invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concept.

Hereinafter, aspects of some embodiments of the present disclosure will be described in more detail with reference to the accompanying drawings.

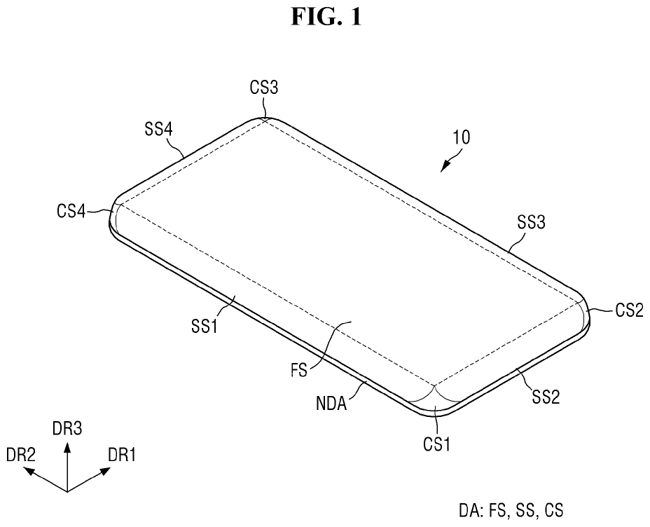

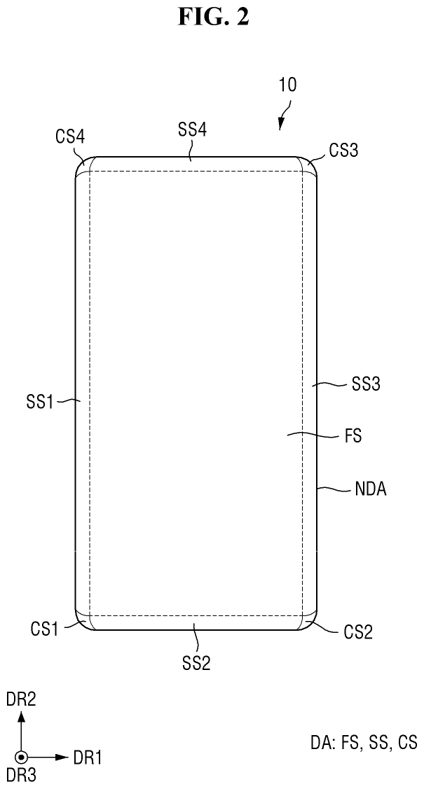

FIG. 1 is a perspective view of a display device 10 according to some embodiments. FIG. 2 is a plan view of the display device 10 of FIG. 1 according to some embodiments.

Referring to FIGS. 1 and 2, the display device 10 according to some embodiments displays a screen or images at a display area DA, which will be described in more detail later, and examples of the display device 10 may include various devices including the display area DA. For example, the display device 10 according to some embodiments of the present specification may be applied to smartphones, mobile phones, tablet personal computers (PCs), personal digital assistants (PDAs), portable multimedia players (PMPs), televisions, game machines, wristwatch-type electronic devices, head mounted displays, monitors of PCs, notebook computers, car navigation systems, car dashboards, digital cameras, camcorders, external billboards, electronic boards, medical devices, examination devices, various home appliances such as refrigerators and washing machines, and Internet of things (IoT) devices.

In the present specification, short sides of the display device 10 may extend in a direction parallel to a first direction DR1 in a plan view, and long sides of the display device 10 may extend in a direction parallel to a second direction DR2 in a plan view. For example, the first direction DR1 and the second direction DR2 may intersect perpendicularly to each other. The first direction DR1 may be a horizontal direction of the display device 10 in a plan view, and the second direction DR2 may be a vertical direction of the display device 10 in a plan view. A third direction DR3 may be a direction perpendicular to the first direction DR1 and the second direction DR2. For example, the third direction DR3 may be a thickness direction of the display device 10.

The display device 10 may include the display area DA and a non-display area NDA.

The display area DA may display images. The display area DA may include pixels and/or light emitting areas. The display area DA may include a front part FS, side parts SS (SS1 through SS4), and corner parts CS (CS1 through CS4).

The entire area of the front part FS may be substantially flat. However, embodiments according to the present disclosure are not limited thereto, and at least a part of the front part FS may also be convex or concave in the thickness direction (the third direction DR3). The front part FS may have a quadrangular shape including short sides in the first direction DR1 and long sides in the second direction DR2. The front part FS may have rounded corners in a plan view. The front part FS may have a polygonal shape with rounded corners in a plan view. For example, as illustrated in FIG. 1, the front part FS may have a quadrangular shape with rounded corners, but embodiments according to the present disclosure are not limited thereto.

The side parts SS (SS1 through SS4) may extend outward from edges of the front part FS and may be bent at an angle (e.g., a set or predetermined angle). For example, the side parts SS may be bent at an angle of 90 to less than 180 degrees with respect to the front part FS. When the front part FS has a quadrangular shape in a plan view, the side parts SS may include a first side part SS1 and a third side part SS3 extending from the front part FS to a first side and a second side in the first direction DR1 and include a second side part SS2 and a fourth side part SS4 extending from the front part FS to a first side and a second side in the second direction DR2. The first through fourth side parts SS1 through SS4 may be substantially the same in function or configuration except for position.

Side surfaces of each of the side parts SS (SS1 through SS4) may have a round shape in a plan view, but the present disclosure is not limited thereto. For example, side surfaces of the first side part SS1 on the first side and the second side in the second direction DR2 may have a round shape in a plan view, but the present disclosure is not limited thereto.

Each of the first through fourth side parts SS1 through SS4 may extend from the front part FS to have a curvature (e.g., a set or predetermined curvature) and may have a round shape. The first through fourth side parts SS1 through SS4 may have a shape convex outward from the display device 10. For example, the first side part

SS1 may have a first curvature, and the second side part SS2 may have a second curvature. The third side part SS3 may have a third curvature, and the fourth side part SS4 may have a fourth curvature. The first through fourth curvatures may be the same. However, the present disclosure is not limited thereto, and the first through fourth curvatures may also be different from each other, or only some of the first through fourth curvatures may be the same.

Each of the corner parts CS may be located between the side parts SS (SS1 through SS4) adjacent to each other. In other words, the first through fourth side parts SS1 through SS4 may be spaced apart from each other in at least some areas by a distance (e.g., a set or predetermined distance). The corner parts CS (CS1 through CS4) may be located in the areas in which the first through fourth side parts SS1 through SS4 are spaced apart from each other.

For example, a first corner part CS1 may be located between the first side part SS1 and the second side part SS2, a second corner part CS2 may be located between the second side part SS2 and the third side part SS3, a third corner part CS3 may be located between the third side part SS3 and the fourth side part SS4, and a fourth corner part CS4 may be located between the fourth side part SS4 and the first side part SS1. The first through fourth corner parts CS1 through CS4 may be substantially the same in function or configuration except for position.

Each of the first through fourth corner parts CS1 through CS4 may have a double curvature and have a round shape. For example, the first corner part CS1 may be located between the first side part SS1 and the second side part SS2. In this case, the first corner part CS1 may have a double curvature including the first curvature of the first side part SS1 and the second curvature of the second side part SS2. The above description of the first corner part CS1 may also be applied to the second through fourth corner parts CS2 through CS4.

Pixels may be located on the corner parts CS as well as the front part FS and the side parts SS of the display device 10, and a screen may be displayed. Accordingly, when the display device 10 is viewed from the front, a user may recognize the screen as being displayed on the entire area of the display device 10. In other words, the user may recognize the screen as if there were substantially no bezel and may be provided with a more immersive screen.

The non-display area NDA may not display an image. The non-display area NDA may not include pixels or light emitting areas. Signal lines or a scan driver for driving the pixels or the light emitting areas may be located in the non-display area NDA. The non-display area NDA may surround the display area DA. The non-display area NDA may be arranged outside the front part FS and the side parts SS and outside the corner parts CS. The non-display area NDA may form a bezel area of the display device 10.

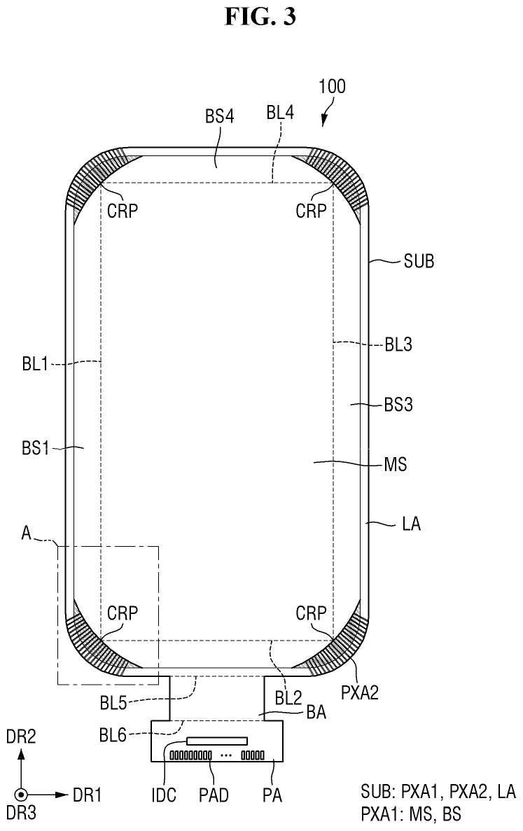

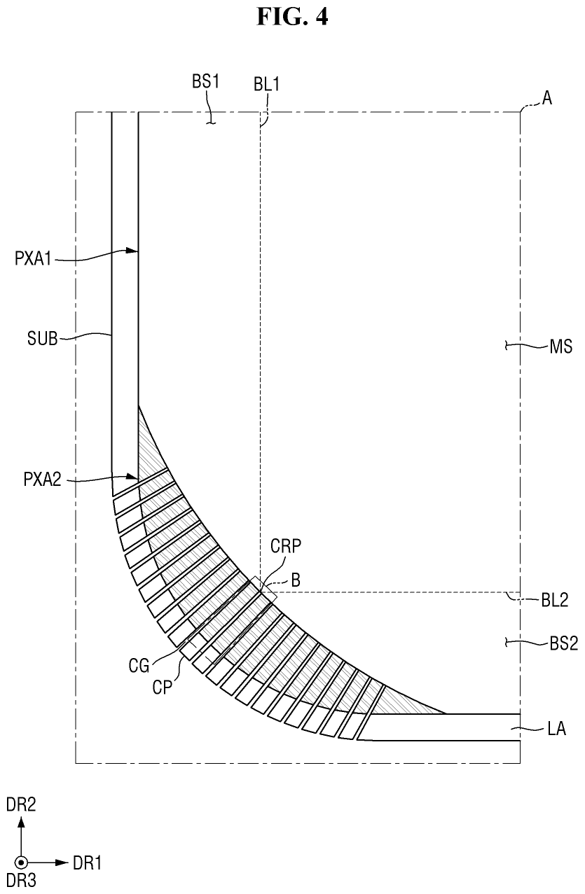

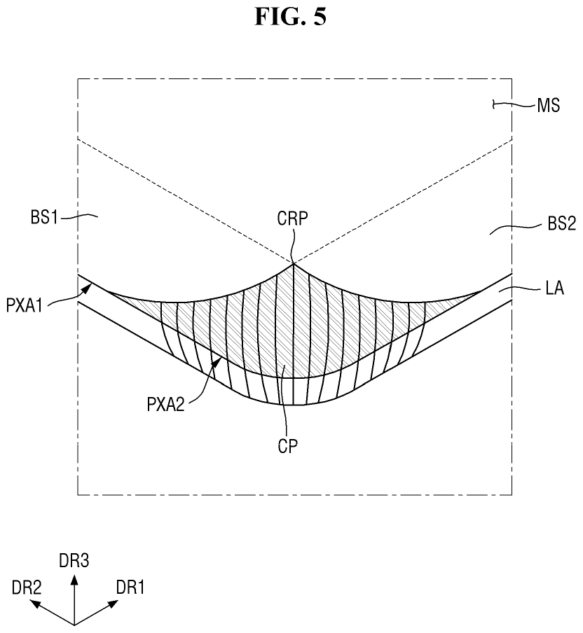

FIG. 3 is a development drawing of a display panel 100 of the display device 10 according to the embodiment. FIG. 4 is an enlarged view of area A of FIG. 3. FIG. 5 is a partial perspective view of the display panel 100 of the display device 10 according to the embodiment. FIG. 5 illustrates a case where area A of FIG. 3 is bent.

The display device 10 according to some embodiments may include the display panel 100. The display panel 100 may be a flexible display panel. In other words, the display panel 100 may be a display panel that can be at least partially bent, folded, and/or rolled.

The display panel 100 may be a light emitting display panel including a light emitting element. For example, the display panel 100 may be at least any one of an organic light emitting display panel using an organic light emitting diode as a light emitting element, a micro light emitting diode display panel using a micro light emitting diode as a light emitting element, a quantum dot light emitting display panel using quantum dot particles, and an inorganic light emitting display panel using an inorganic semiconductor as a light emitting element. The display panel 100 will hereinafter be described as an organic light emitting display panel.

The display panel 100 may include a substrate SUB. As will be described later, the substrate SUB may provide a space in which other elements located on the substrate SUB can be located and may support the elements located on the substrate SUB.

The substrate SUB may include a first pixel area PXA1, a second pixel area PXA2, and a non-pixel area LA. Each of the first pixel area PXA1 and the second pixel area PXA2 may include a plurality of pixels. In the non-pixel area LA, pixels may not be located, and wirings for driving the pixels may be located. The first pixel area PXA1 and the second pixel area PXA2 may correspond to the display area DA (see FIG. 1) of the display device 10 (see FIG. 1), and the non-pixel area LA may correspond to the non-display area NDA (see FIG. 1) of the display device 10 (see FIG. 1). The non-pixel area LA may be located outside the first pixel area PXA1 and the second pixel area PXA2 and may surround the first pixel area PXA1 and the second pixel area PXA2 in the development drawing.

The first pixel area PXA1 may include a main part MS and bending parts BS (BS1 through BS4). The main part MS may correspond to the front part FS (see FIG. 1) of the display device 10 (see FIG. 1), and the bending parts BS (BS1 through BS4) may correspond to the side parts SS (see FIG. 1) of the display device 10 (see FIG. 1). The shape of the main part MS may substantially correspond to that of the front part

FS (see FIG. 1) of the display device 10 (see FIG. 1), and the shape of the bending parts BS (BS1 through BS4) may substantially correspond to that of the side parts SS (see FIG. 1) of the display device 10 (see FIG. 1).

The bending parts BS (BS1 through BS4) may extend outward from edges of the main part MS and may be bent at an angle (e.g., a set or predetermined angle). Each of first through fourth bending parts BS1 through BS4 may extend from the main part MS and may be bent along a bending line BL1, BL2, BL3 or BL4. For example, the bending parts BS may be bent at an angle of 90 to less than 180 degrees with respect to the main part MS.

An intersection point CRP of two of the bending lines BL1 through BL4 may be located between the first pixel area PXA1 and the second pixel area PXA2 or may be located on the boundary between the first pixel area PXA1 and the second pixel area PXA2. However, the present disclosure is not limited thereto, and the intersection point CRP may also be located in the first pixel area PXA1 or in the second pixel area PXA2.

When the main part MS has a quadrangular shape in a plan view, the bending parts BS may include the first bending part BS1 and the third bending part BS3 extending from the main part MS to the first side and the second side in the first direction DR1 and include the second bending part BS2 and the fourth bending part BS4 extending from the main part MS to the first side and the second side in the second direction DR2. The first through fourth bending parts BS1 through BS4 may be substantially the same in function or configuration except for position.

Each of the first through fourth bending parts BS1 through BS4 may extend from the main part MS to have a curvature (e.g., a set or predetermined curvature) and may have a round shape. For example, the first bending part BS1 may have a curvature convex toward the first side in the first direction DR1 and a first side in the third direction DR3. The curvature of the first bending part BS1 may be, but is not limited to, substantially the same as the first curvature of the first side part SS1 of the display device 10 (see FIG. 1). The first through fourth bending parts BS1 through BS4 may have substantially the same curvature. However, the present disclosure is not limited thereto, and the first through fourth bending parts BS1 through BS4 may also have different curvatures.

Each of the first through fourth bending parts BS1 through BS4 may have a generally trapezoidal shape in the development drawing. In this case, both side surfaces of the trapezoidal shape may have a round shape. For example, in the development drawing, a length to which a side of the first bending part BS1 on the first side in the first direction DR1 extends in the second direction DR2 may be smaller than a length to which a side of the first bending part BS1 on the second side in the first direction DR1 extends in the second direction DR2. Side surfaces connecting the above two sides of the first bending part BS1 may be located on one side and the other side of the first bending part BS1 in the second direction DR2 in the development drawing and may have a round shape. However, the shape of the first bending part BS1 in the development drawing is not limited thereto. The description of the first bending part BS1 may also be applied to the second through fourth bending parts BS2 through BS4.

The second pixel area PXA2 may be located between the bending parts BS (BS1 through BS4) adjacent to each other. In other words, the first through fourth bending parts BS1 through BS4 may be spaced apart from each other in at least some areas by a distance (e.g., a set or predetermined distance). The second pixel area PXA2 may be located in the areas in which the first through fourth bending parts BS1 through BS4 are spaced apart from each other.

For example, the second pixel area PXA2 may be located in at least any one of an area between the first bending part BS1 and the second bending part BS2, an area between the second bending part BS2 and the third bending part BS3, an area between the third bending part BS3 and the fourth bending part BS4, and an area between the fourth bending part BS4 and the first bending part BS1.

The second pixel area PXA2 may have a double curvature and have a round shape. For example, the second pixel area PXA2 located between the first bending part BS1 and the second bending part BS2 may have a double curvature including the curvature of the first bending part BS1 and the curvature of the second bending part BS2. The shape of the second pixel area PXA2 may correspond to the shape of each corner part CS (see FIG. 1) of the display device 10 (see FIG. 1).

The substrate SUB may include protruding patterns CP. The protruding patterns CP may protrude from the first pixel area PXA1 (or a base) of the substrate SUB. In other words, the protruding patterns CP may protrude from at least any one of the main part MS and the bending parts BS (BS1 through BS4). The protruding patterns CP adjacent to each other may be physically separated from each other in at least some areas. As will be described later, the protruding patterns CP may be physically separated from each other from an uppermost layer to the substrate SUB, which is a lowermost layer, in at least some areas.

A cut part CG (or a cut pattern) may be located in a part where adjacent protruding patterns CP are physically separated from each other. That is, a space may be provided between the protruding patterns CP adjacent to each other by the cut part CG. Accordingly, even if the second pixel area PXA2 has a double curvature, strain applied to the second pixel area PXA2 may be reduced by the cut parts CG because the protruding patterns CP of the second pixel area PXA2 can stretch and contract.

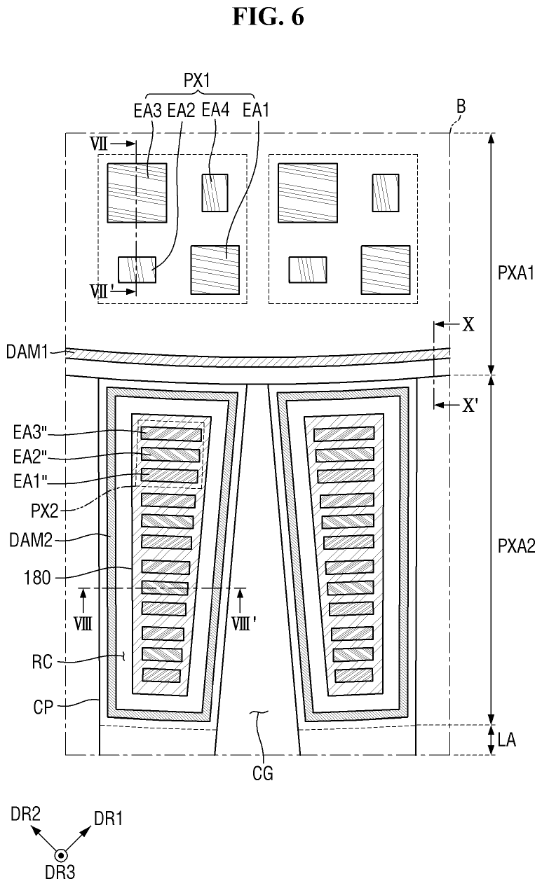

FIG. 6 is an enlarged view of area B of FIG. 4.

Referring to FIGS. 3 through 6, the first pixel area PXA1 may include a plurality of first pixels PX1, and the second pixel area PXA2 may include a plurality of second pixels PX2.

Each of the first pixels PX1 of the first pixel area PXA1 may include a plurality of light emitting areas EA1 through EA4. For example, each of the first pixels PX1 may include a first light emitting area EA1, a second light emitting area EA2, a third light emitting area EA3, and a fourth light emitting area EA4. The first light emitting area EA1, the second light emitting area EA2, the third light emitting area EA3, and the fourth light emitting area EA4 may emit light of different colors, but the present disclosure is not limited thereto.

The first pixel area PXA1 may further include a first dam structure DAM1. The first dam structure DAM1 may be arranged along edges of the first pixel area PXA1. The first dam structure DAM1 may surround the first pixels PX1 of the first pixel area PXA1 in a plan view. The first dam structure DAM1 may suppress or prevent an organic material layer of the first pixel area PXA1 from overflowing to the outside of the first pixel area PXA1.

Each of the second pixels PX2 of the second pixel area PXA2 may include a plurality of light emitting areas EA1″ through EA3″. For example, each of the second pixels PX2 may include a first light emitting area EA1″, a second light emitting area EA2″, and a third light emitting area EA3″. The first light emitting area EA1″, the second light emitting area EA2″, and the third light emitting area EA3″ may emit light of different colors, but the present disclosure is not limited thereto.

The second pixel area PXA2 may further include a second dam structure DAM2. The second dam structure DAM2 may be arranged along edges of each protruding pattern CP of the second pixel area PXA2. In other words, the second dam structure DAM2 may be located on each protruding pattern CP and may surround the second pixels PX2 located on each protruding pattern CP. The second dam structure DAM2 may suppress or prevent an organic material layer of each protruding pattern CP of the second pixel area PXA2 from overflowing to the outside of each protruding pattern CP of the second pixel area PXA2.

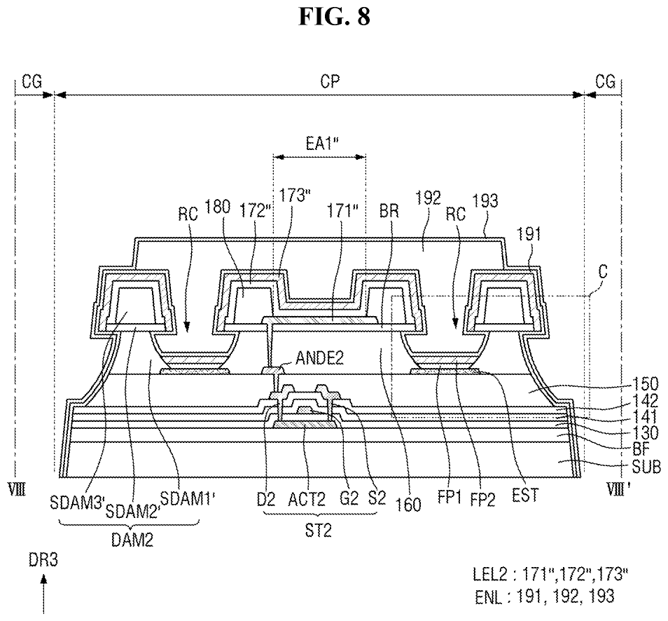

A recess pattern RC may be located inside the second dam structure DAM2 on each protruding pattern CP of the second pixel area PXA2. Due to the recess pattern RC, an organic layer 172″ (see FIG. 8) of each second pixel PX2 of the second pixel area PXA2 may be separated from a dummy organic layer FP1 (see FIG. 8) located in the recess pattern RC. In addition, the penetration of outside air and moisture into the organic layer 172″ of each second pixel PX2 of the second pixel area

PXA2 may be suppressed or prevented by the dummy organic layer FP1. Therefore, the reliability of the second pixels PX2 of the second pixel area PXA2 can be improved.

The protruding patterns CP may protrude from at least any one of the main part MS and the bending parts BS of the first pixel area PXA1 toward the outside of the first pixel area PXA1. The protruding patterns CP may protrude from the first pixel area PXA1. One end of each protruding pattern CP may be connected to the first pixel area PXA1. The non-pixel area LA may be located on an opposite side of each protruding pattern CP connected to the first pixel area PXA1.

One end of each protruding pattern CP may be connected to the first pixel area PXA1. The other end of each protruding pattern CP may be connected to the non-pixel area LA. In other words, in some areas of the display panel 100, the first pixel area PXA1 and the non-pixel area LA may be spaced apart from each other with the second pixel area PXA2 interposed between them. The protruding patterns CP of the second pixel area PXA2 may be located in a space between the first pixel area PXA1 and the non-pixel area LA and may connect the first pixel area PXA1 and the non-pixel area LA. However, the present disclosure is not limited thereto. For example, the other end of each protruding pattern CP may not be connected to the non-pixel area LA and may be exposed to the outside without being connected to a separate element.

Each protruding pattern CP may be located in the second pixel area PXA2 between the first pixel area PXA1 and the non-pixel area LA. The non-pixel area LA may be provided for each protruding pattern CP, and the non-pixel areas LA respectively provided for the protruding patterns CP may be separated and spaced apart from each other in a development drawing.

In the development drawing, each protruding pattern CP may be exposed, except for a part connected to the first pixel area PXA1. The protruding patterns CP may have different lengths in a direction in which the protruding patterns CP protrude from the first pixel area PXA1. In the development drawing, an end of the first pixel area PXA1 from which the protruding patterns CP protrude may include a curve. In this case, the protruding patterns CP may protrude in different directions. However, the present disclosure is not limited thereto. The length of each protruding pattern CP in the direction in which the protruding pattern CP protrudes from the first pixel area PXA1 may be greater than a width of the protruding pattern CP in a direction perpendicular to the protruding direction.

The width of each of the protruding patterns CP may be reduced from the first pixel area PXA1 toward the non-pixel area LA. In this case, in the development drawing, each of the protruding patterns CP may have a trapezoidal shape in a plan view, but the present disclosure is not limited thereto.

The protruding patterns CP may face each other. In other words, the protruding patterns CP may be spaced apart from each other with the cut part CG interposed between them, and side surfaces of the protruding patterns CP may face each other. The protruding patterns CP may be separated by the cut part CG. In the development drawing, a distance between the protruding patterns CP adjacent to each other may increase from the first pixel area PXA1 toward the non-pixel area LA.

When the protruding patterns CP are bent, the distance between the protruding patterns CP adjacent to each other may be reduced, or the protruding patterns CP adjacent to each other may directly contact each other. When the protruding patterns CP adjacent to each other directly contact each other, a physical interface (or boundary) may be located between the protruding patterns CP adjacent to each other. However, the present disclosure is not limited thereto. When the protruding patterns CP adjacent to each other are bent, they may also overlap each other. Furthermore, when the protruding patterns CP are bent, a distance between the second pixels PX2 located on each protruding pattern CP may be reduced.

In addition, when an outermost protruding pattern CP among the protruding patterns CP is bent, it may directly contact an adjacent bending part BS1, BS2, BS3 or BS4. In this case, a physical interface (or boundary) may be located between the outermost protruding pattern CP and the first pixel area PXA1 adjacent to the outermost protruding pattern CP and located in the bending part BS1, BS2, BS3 or

BS4.

When the protruding patterns CP are bent, they may have a double curvature and have a round shape. In other words, the protruding patterns CP may have substantially the same double curvature as the second pixel area PXA2 and may have a round shape.

The display panel 100 may further include a bending area BA and a pad area PA.

The bending area BA may extend from a lower side of the non-pixel area LA in the development drawing. The bending area BA may be located between the non-pixel area LA and the pad area PA. A length of the bending area BA in the first direction DR1 may be smaller than a length of the non-pixel area LA in the first direction DR1. The bending area BA may be bent along a fifth bending line BL5 on the lower side of the non-pixel area LA.

The pad area PA may extend downward from the bending area BA in a plan view. A length of the pad area PA in the first direction DR1 may be greater than the length of the bending area BA in the first direction DR1. However, the present disclosure is not limited thereto. The length of the pad area PA in the first direction DR1 may also be substantially the same as the length of the bending area BA in the first direction DR1. The pad area PA may be bent along a sixth bending line BL6 on the lower side of the bending area BA. The pad area PA may be located on a lower surface of the main part MS.

An integrated driving circuit IDC and pads PAD may be located in the pad area PA. The integrated driving circuit IDC may be formed as an integrated circuit. The integrated driving circuit IDC may be attached into the pad area PA using a chip on glass (COG) method, a chip on plastic (COP) method, or an ultrasonic bonding method. Alternatively, the integrated driving circuit IDC may be located on a circuit board located on the pads PAD of the pad area PA.

The integrated driving circuit IDC may be electrically connected to the pads PAD of the pad area PA. The integrated driving circuit IDC may receive digital video data and timing signals through the pads PAD of the pad area PA. The integrated driving circuit IDC may convert the digital video data into analog data voltages and output the analog data voltages to data lines of the display area DA.

A cross section of the display panel 100 will now be described.

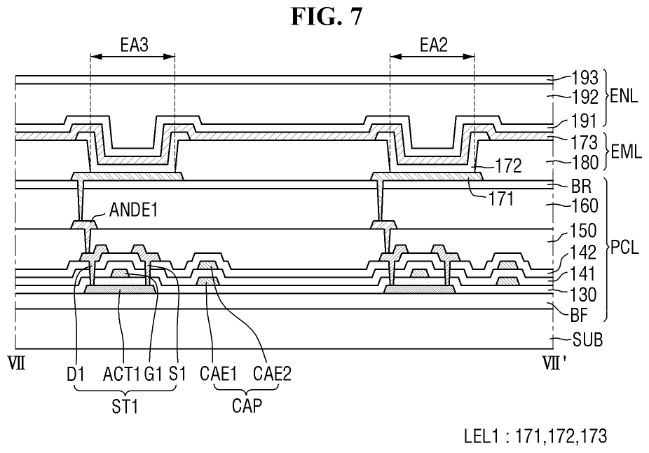

FIG. 7 is a cross-sectional view taken along line VII-VII′ of FIG. 6. FIG. 7 illustrates the stacked structure of the first pixel area PXA1.

Referring to FIGS. 6 and 7, the first pixel area PXA1 of the display panel 100 may include the substrate SUB, a pixel circuit layer PCL, a light emitting element layer EML, and an encapsulation layer ENL.

The substrate SUB supports each layer located thereon. The substrate SUB may be made of an insulating material such as polymer resin or an inorganic material such as glass or quartz. In addition, the substrate SUB may have a multilayer structure of polymer resin and an inorganic layer. However, the present disclosure is not limited thereto, and the substrate SUB may also be a transparent plate or a transparent film.

The substrate SUB may be a flexible substrate that can be bent, folded, rolled, etc. However, the present disclosure is not limited thereto, and the substrate SUB may also be a rigid substrate.

The pixel circuit layer PCL is located on the substrate SUB. The pixel circuit layer PCL may include first thin-film transistors ST1, first connection electrodes ANDE1, a buffer layer BF, a gate insulating layer 130, a first interlayer insulating film 141, a second interlayer insulating film 142, a first planarization layer 150, and a second planarization layer 160.

For example, the buffer layer BF may be located on the substrate SUB. The buffer layer BF may block impurities that can be introduced from under the buffer layer BF, improve adhesion of elements located on the buffer layer BF, and perform a planarization function. The buffer layer BF may be made of a silicon nitride layer, a silicon oxynitride layer, a silicon oxide layer, a titanium oxide layer, or an aluminum oxide layer.

First thin-film transistors ST1 may be located on the buffer layer BF. Each of the first thin-film transistor ST1 may include a first active layer ACT1, a first gate electrode G1, a first source electrode 51, and a first drain electrode D1.

The first active layer ACT1 of each of the first thin-film transistors ST1 may be located on the buffer layer BF. The first active layer ACT1 may include a silicon semiconductor such as polycrystalline silicon, monocrystalline silicon, low-temperature polycrystalline silicon, or amorphous silicon. The first active layer ACT1 may include a channel region in a region overlapping the first gate electrode G1 in the thickness direction (the third direction DR3) and source/drain regions located on one side and the other side of the channel region.

The gate insulating layer 130 may be located on the first active layers ACT1 of the first thin-film transistors ST1. The gate insulating layer 130 may be made of an inorganic layer, for example, a silicon nitride layer, a silicon oxynitride layer, a silicon oxide layer, a titanium oxide layer, or an aluminum oxide layer.

The first gate electrodes G1 of the first thin-film transistors ST1 and first capacitor electrodes CAE1 may be located on the gate insulating layer 130. The first gate electrodes G1 of the first thin-film transistor ST1 may overlap the first active layers ACT1 in the third direction DR3. The first capacitor electrodes CAE1 may overlap second capacitor electrodes CAE2 in the third direction DR3. Each of the first gate electrodes G1 and the first capacitor electrodes CAE1 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The first interlayer insulating film 141 may be located on the first gate electrodes G1 and the first capacitor electrodes CAE1. The first interlayer insulating film 141 may include an inorganic layer.

The second capacitor electrodes CAE2 may be located on the first interlayer insulating film 141. The second capacitor electrodes CAE2 may overlap the first capacitor electrodes CAE1 in the third direction DR3. The first capacitor electrodes CAE1, the second capacitor electrodes CAE2, and the first interlayer insulating film 141 may form capacitors CAP. Each of the second capacitor electrodes CAE2 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The second interlayer insulating film 142 may be located on the second capacitor electrodes CAE2. The second interlayer insulating film 142 may include an inorganic layer.

The first source electrode S1 and the first drain electrode D1 of each of the first thin-film transistors ST1 may be located on the second interlayer insulating film 142. Each of the first source electrode S1 and the first drain electrode D1 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The first source electrode S1 of each of the first thin-film transistors ST1 may be connected to a conductive region located on one side of the channel region of the first active layer ACT1 through a contact hole passing through the gate insulating layer 130, the first interlayer insulating film 141, and the second interlayer insulating film 142. The first drain electrode D1 of each of the first thin-film transistors ST1 may be connected to a conductive region located on the other side of the channel region of the first active layer ACT1 through a contact hole passing through the gate insulating layer 130, the first interlayer insulating film 141, and the second interlayer insulating film 142.

The first planarization layer 150 may be located on the first source electrodes S1 and the first drain electrodes D1 to flatten steps due to thin-film transistors. The first planarization layer 150 may be made of an organic layer such as acryl resin, epoxy resin, phenolic resin, polyamide resin, or polyimide resin.

The first connection electrodes ANDE1 may be located on the first planarization layer 150. The first connection electrodes ANDE1 may be connected to the first source electrodes S1 or the first drain electrodes D1 of the first thin-film transistors ST1 through contact holes passing through the first planarization layer 150. Each of the first connection electrodes ANDE1 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

The second planarization layer 160 may be located on the first connection electrodes ANDE1. The second planarization layer 160 may include an organic layer such as acryl resin, epoxy resin, phenolic resin, polyamide resin, or polyimide resin.

A barrier layer BR may be located on the second planarization layer 160. The barrier layer BR may include an inorganic layer.

The light emitting element layer EML is located on the pixel circuit layer PCL. The light emitting element layer EML may include first light emitting elements LEL1 and a pixel defining layer 180.

Each of the first light emitting elements LEL1 may include a pixel electrode 171, an organic layer 172, and a common electrode 173. Each of the light emitting areas EA1 through EA4 may be an area in which the pixel electrode 171, the organic layer 172, and the common electrode 173 are sequentially stacked so that holes from the pixel electrode 171 and electrons from the common electrode 173 combine together in the organic layer 172 to emit light. In this case, the pixel electrode 171 may be an anode, and the common electrode 173 may be a cathode. The first light emitting area EA1, the second light emitting area EA2, and the fourth light emitting area EA4 may be substantially the same as the third light emitting area EA3 illustrated in FIG. 7.

For example, the pixel electrodes 171 may be located on the barrier layer BR. The pixel electrodes 171 may be connected to the first connection electrodes ANDE1 through contact holes passing through the barrier layer BR and the second planarization layer 160.

In a top emission structure in which light is emitted from the organic layers 172 toward the common electrode 173, each of the pixel electrodes 171 may be formed as a single layer of molybdenum (Mo), titanium (Ti), copper (Cu) or aluminum (Al) or may have a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 180 may define the light emitting areas EA1 through EA4 of pixels. To this end, the pixel defining layer 180 may be formed on the barrier layer BR to expose a part of each of the pixel electrodes 171. The pixel defining layer 180 may cover edges of the pixel electrodes 171. The pixel electrodes 171 may be located in contact holes passing through the barrier layer BR and the second planarization layer 160. Accordingly, the contact holes passing through the barrier layer BR and the second planarization layer 160 may be filled with the pixel electrodes 171. The pixel defining layer 180 may be made of an organic layer such as acryl resin, epoxy resin, phenolic resin, polyamide resin, or polyimide resin.

The organic layers 172 are located on the pixel electrodes 171 exposed by the pixel defining layer 180. The organic layers 172 may include an organic material to emit light of a color (e.g., a set or predetermined color). For example, each of the organic layers 172 may include a hole injection/transporting layer, a light emitting layer, and an electron injection/transporting layer. The light emitting layer may include a host and a dopant. The light emitting layer may include a material emitting light (e.g., a set or predetermined light) and may be formed using a phosphorescent material or a fluorescent material.

The common electrode 173 is located on the organic layers 172. The common electrode 173 may cover the organic layers 172. The common electrode 173 may be a common layer common to all pixels. A capping layer may be formed on the common electrode 173.

In the top emission structure, the common electrode 173 may be made of a transparent conductive material (TCO) capable of transmitting light, such as indium tin oxide (ITO) or indium zinc oxide (IZO), or a semi-transmissive conductive material such as magnesium (Mg), silver (Ag) or an alloy of Mg and Ag. When the common electrode 173 is made of a semi-transmissive conductive material, light output efficiency may be increased by a microcavity.

The encapsulation layer ENL may be formed on the light emitting element layer EML. The encapsulation layer ENL may include at least one inorganic layer to prevent oxygen or moisture from permeating into the light emitting element layer EML. In addition, the encapsulation layer ENL may include at least one organic layer to protect the light emitting element layer EML from particles.

For example, the encapsulation layer ENL may include a first encapsulating inorganic layer 191 located on the common electrode 173, an encapsulating organic layer 192 located on the first encapsulating inorganic layer 191, and a second encapsulating inorganic layer 193 located on the encapsulating organic layer 192. Each of the first encapsulating inorganic layer 191 and the second encapsulating inorganic layer 193 may be a multilayer in which one or more inorganic layers selected from a silicon nitride layer, a silicon oxynitride layer, a silicon oxide layer, a titanium oxide layer, and an aluminum oxide layer are stacked. The encapsulating organic layer 192 may include at least any one of acryl resin, epoxy resin, phenolic resin, polyamide resin, and polyimide resin.

According to some embodiments, a touch member may be further located on the encapsulation layer ENL. The touch member is an element separate from the display panel 100 and may be located on the encapsulation layer ENL or may be integrally formed with the display panel 100.

The stacked structure of the second pixel area PXA2 will now be described.

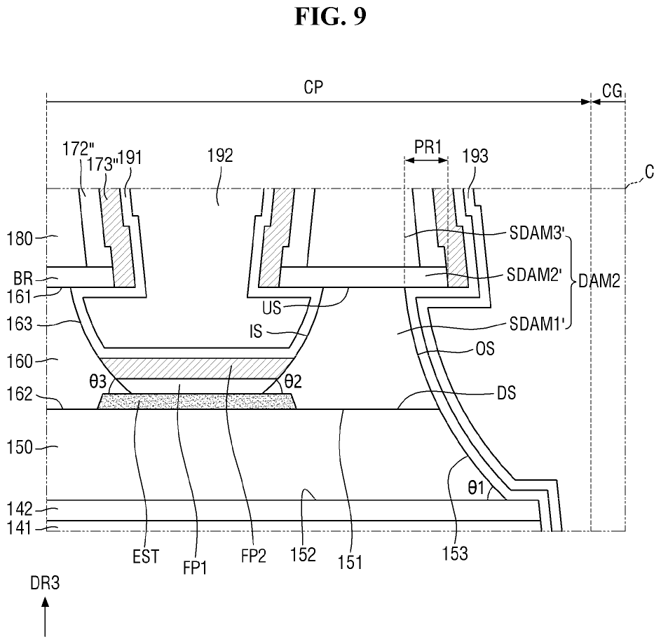

FIG. 8 is a cross-sectional view taken along line VIII-VIII′ of FIG. 6. FIG. 9 is an enlarged view of area C of FIG. 8. FIG. 8 illustrates the stacked structure of the second pixel area PXA2. The stacked structure of the second pixel area PXA2 may be substantially the same as the stacked structure of the first pixel area PXA1. Therefore, any redundant description will be omitted below, and only differences will be described.

The second pixel area PXA2 may include a second thin-film transistor ST2, a second light emitting element LEL2, and the encapsulation layer ENL. The second thin-film transistor ST2 may include a second active layer ACT2, a second gate electrode G2, a second source electrode S2, and a second drain electrode D2. The second thin-film transistor ST2 may include substantially the same configuration as the first thin-film transistors ST1 of the first pixel area PXA1 of FIG. 7. Therefore, a detailed description of the second thin-film transistor ST2 will be omitted.

The display device 10 may further include an etch stop pattern EST. The etch stop pattern EST may be located on the first planarization layer 150. The etch stop pattern EST may overlap the recess pattern RC in the thickness direction (the third direction DR3). The etch stop pattern EST may be exposed by the recess pattern RC. The etch stop patterns EST may include an inorganic material, but the present disclosure is not limited thereto. The etch stop pattern EST may be located around the second dam structure DAM2 and may serve as an etch stopper in the process of forming the second dam structure DAM2.

Furthermore, a conductive line electrically connected to the second pixels PX2 to apply a voltage or transmit a signal may be located under the etch stop pattern

EST. In this case, the etch stop pattern EST may prevent the conductive line thereunder from being damaged by etching. At least a part of the etch stop pattern EST may overlap the second dam structure DAM2 in the thickness direction (the third direction DR3).

The second light emitting element LEL2 of the second pixel area PXA2 may include a pixel electrode 171″, an organic layer 172″, and a common electrode 173″. The second light emitting element LEL2 of the second pixel area PXA2 may include substantially the same configuration as the first light emitting elements LEL1 of the light emitting element layer EML of FIG. 7. Therefore, a description of the second light emitting element LEL2 of the second pixel area PXA2 will be omitted. Furthermore, the pixel electrode 171″ of the second light emitting element LEL2 and the second drain electrode D2 of the second thin-film transistor ST2 may be electrically connected by a second connection electrode ANDE2 located on the first planarization layer 150.

The encapsulation layer ENL of the second pixel area PXA2 may include the first encapsulating inorganic layer 191, the encapsulating organic layer 192, and the second encapsulating inorganic layer 193. The encapsulation layer ENL of the second pixel area PXA2 may include substantially the same configuration as the encapsulation layer ENL of the first pixel area PXA1, and thus a description thereof will be omitted.

In addition, the first encapsulating inorganic layer 191 and the second encapsulating inorganic layer 193 may be located on cut surfaces or side surfaces of each protruding pattern CP. For example, the first encapsulating inorganic layer 191 and the second encapsulating inorganic layer 193 may be located on cut surfaces or side surfaces of the substrate SUB, the buffer layer BF, the gate insulating layer 130, the first interlayer insulating film 141, the second interlayer insulating film 142, and the first planarization layer 150 of each protruding pattern CP. Therefore, it is possible to prevent moisture or oxygen from being introduced through the cut surfaces or side surfaces of each protruding pattern CP and damaging the organic layer 172″.

The second pixel area PXA2 may further include the barrier layer BR. The barrier layer BR may be located between the second planarization layer 160 and the pixel electrode 171″. The barrier layer BR may include an inorganic layer.

In the second pixel area PXA2, the second dam structure DAM2 may be located on the first planarization layer 150. The second dam structure DAM2 may include a first sub-dam SDAM1′ including the same material as the second planarization layer 160, a second sub-dam SDAM2′ including the same material as the barrier layer BR, and a third sub-dam SDAM3′ including the same material as the pixel defining layer 180. The first sub-dam SDAM1′, the second sub-dam SDAM2′, and the third sub-dam SDAM3′ may be sequentially stacked.

A side surface of the second sub-dam SDAM2′ may protrude further than an outer side surface OS of the first sub-dam SDAM1′ by a first length PR1. In other words, a side surface of the second sub-dam SDAM2′ may protrude outward by the first length PR1 from a corner where a first surface US of the first sub-dam SDAM1′ meets the outer side surface OS.

The second pixel area PXA2 may further include the recess pattern RC. The recess pattern RC may be located between the second dam structure DAM2 and the light emitting areas EA1″ through EA3″ in a plan view. In other words, the recess pattern RC may be located outside the light emitting areas EA1″ through EA3″ of the second pixels PX2 in a plan view and may be located inside the second dam structure DAM2 in a plan view. The recess pattern RC may surround the pixel defining layer 180 in a plan view and may surround the light emitting areas EA1″ through EA3″ of the second pixels PX2 in a plan view, but the present disclosure is not limited thereto.

When the recess pattern RC surrounds the light emitting areas EA1″ through EA3″, the second planarization layer 160 and the first sub-dam SDAM1′ may be separated from each other on each protruding pattern CP, and the second planarization layer 160 may include an island shape. In addition, the barrier layer BR and the second sub-dam SDAM2′ are separated from each other on each protruding pattern CP, and the barrier layer BR may include an island shape. However, the present disclosure is not limited thereto. When the recess pattern RC does not surround the light emitting areas EA1″ through EA3″ in a plan view, the second planarization layer 160 and the first sub-dam SDAM1′ may be connected to each other, and the barrier layer BR and the second sub-dam SDAM2′ may be connected to each other in an area where the recess pattern RC is not located.

The recess pattern RC may be defined by the barrier layer BR, the second planarization layer 160, the first sub-dam SDAM1′, and the second sub-dam SDAM2′.

In this case, sidewalls of the recess pattern RC may be composed of the barrier layer BR, the second planarization layer 160, the first sub-dam SDAM1′, and the second sub-dam SDAM2′. However, the present disclosure is not limited thereto, and the sidewalls of the recess pattern RC may further include the pixel defining layer 180 and the third sub-dam SDAM3′. The recess pattern RC may expose the etch stop pattern EST. The recess pattern RC may have, but is not limited to, an undercut shape.

For example, the first planarization layer 150 located on each protruding pattern CP may include a first surface 151 (or an upper surface), a second surface 152 (or a lower surface) opposite the first surface 151, and side surfaces 153 connecting the first surface 151 and the second surface 152. The second planarization layer 160 located on each protruding pattern CP may include a first surface 161 (or an upper surface), a second surface 162 (or a lower surface) opposite the first surface 161, and side surfaces 163 connecting the first surface 161 and the second surface 162. The first sub-dam SDAM1′ may include the first surface US (or an upper surface), a second surface DS (or a lower surface) opposite the first surface US, first side surfaces IS (or inner side surfaces) connecting the first surface US and the second surface DS, and second side surfaces OS (or outer side surfaces) connecting the first surface US and the second surface DS. The outer side surfaces OS of the first sub-dam SDAM1′ may be aligned with the side surfaces 153 of the first planarization layer 150, but the present disclosure is not limited thereto. Similarly, each of the barrier layer BR and the second sub-dam SDAM2′ may include a first surface, a second surface, and side surfaces.

The side surfaces of the barrier layer BR may protrude further outward than the side surfaces 163 of the second planarization layer 160. Here, ‘outward’ may refer to a direction toward the center of the recess pattern RC or a direction from a sidewall of the recess pattern RC toward the other sidewall of the recess pattern RC which faces the above sidewall. In other words, the side surfaces of the barrier layer BR may protrude further toward the center of the recess pattern RC than the side surfaces 163 of the second planarization layer 160. A distance between each side surface of the barrier layer BR and the second sub-dam SDAM2′ may be smaller than a distance between each side surface 163 of the second planarization layer 160 and an inner side surface IS the first sub-dam SDAM1′.

The side surfaces 153 of the first planarization layer 150 may face the outside of each protruding pattern CP, that is, may face the cut parts CG. The side surfaces 153 of the first planarization layer 150 may face the side surfaces 153 of the first planarization layers 150 located on adjacent protruding patterns CP. The side surfaces 163 of the second planarization layer 160 and the inner side surfaces IS of the first sub-dam SDAM1′ may face each other. The outer side surfaces OS of the first sub-dam SDAM1′ may face the outside of each protruding pattern CP, that is, may face the cut parts CG. The outer side surfaces OS of the first sub-dam SDAM1′ may face the outer side surfaces OS of the first sub-dams SDAM1′ of the adjacent protruding patterns CP. The recess pattern RC may be defined by the side surfaces 163 of the second planarization layer 160, the inner side surfaces IS of the first sub-dam SDAM1′, the side surfaces of the barrier layer BR, and the second sub-dam SDAM2′.

When the recess pattern RC covers the etch stop pattern EST, the side surfaces 163 of the second planarization layer 160 and the inner side surfaces IS of the first sub-dam SDAM1′ may be connected to each other.

The dummy organic layer FP1 may be located in the recess pattern RC. The dummy organic layer FP1 may be located on the etch stop pattern EST exposed by the recess pattern RC. When the recess pattern RC has an undercut shape, the organic layer 172″ may not be located on the sidewalls of the recess pattern RC. Therefore, the organic layer 172″ may be separated from the dummy organic layer FP1. The dummy organic layer FP1 may be a remaining part of the organic layer 172″ which is separated from a part of the organic layer 172″ emitting light without being connected to the part of the organic layer 172″. The dummy organic layer FP1 may be made of the same material as the organic layer 172″.

A dummy common electrode layer FP2 may be located in the recess pattern RC. The dummy common electrode layer FP2 may be located on the dummy organic layer FP1. When the recess pattern RC has an undercut shape, the common electrode 173″ may not be located on the sidewalls of the recess pattern RC. Therefore, the common electrode 173″ may be separated from the dummy common electrode layer FP2. The dummy common electrode layer FP2 may be a remaining part of the common electrode 173″ which is separated from a part of the common electrode 173″ providing electrons without being connected to the part of the common electrode 173″. The dummy common electrode layer FP2 may be made of the same material as the common electrode 173″.

The first encapsulating inorganic layer 191 may be located on the dummy common electrode layer FP2 in the recess pattern RC and may cover the dummy common electrode layer FP2. The first encapsulating inorganic layer 191 may be located on the side surfaces of the second planarization layer 160 defining the recess pattern RC and may also be located on the second surface (lower surface) of the barrier layer BR protruding toward the recess pattern RC. That is, the first encapsulating inorganic layer 191 may cover the second planarization layer 160 and the barrier layer BR exposed by the common electrode 173″ and the dummy common electrode layer FP2. The barrier layer BR protruding toward the recess pattern RC may directly contact the first encapsulating inorganic layer 191, thereby facilitating encapsulation of an organic layer.

The encapsulating organic layer 192 may be located on the first encapsulating inorganic layer 191 and may fill the recess pattern RC. The encapsulating organic layer 192 may be located inside the second dam structure

DAM2 and may not be located beyond the second dam structure DAM2. The second encapsulating inorganic layer 193 may be located on the encapsulating organic layer 192 and may be located on the first encapsulating inorganic layer 191 outside the second dam structure DAM2 to encapsulate the encapsulating organic layer 192.

A first angle θ1 formed by each side surface 153 and the second surface 152 of the first planarization layer 150 may be in the range of 20 to 80 degrees, in the range of 30 to 60 degrees, or in the range of 40 to 50 degrees.

A second angle θ2 formed by each inner side surface IS and the second surface DS of the first sub-dam SDAM1′ may be in the range of 20 to 80 degrees, in the range of 30 to 60 degrees, or in the range of 40 to 50 degrees. A third angle θ3 formed by each side surface 163 and the second surface 162 of the second planarization layer 160 may be in the range of 20 to 80 degrees, in the range of 30 to 60 degrees, or in the range of 40 to 50 degrees.

The first angle θ1 may be substantially the same as any one of the second angle θ2 and the third angle θ3. However, the present disclosure is not limited thereto. When the second angle θ2 and the third angle θ3 are substantially the same, the first angle θ1 may be substantially the same as the second angle θ2 and the third angle θ3.

When the first angle θ1 is within the above range, encapsulation by the encapsulation layer ENL may be facilitated. In other words, the first encapsulating inorganic layer 191 outside the second dam structure DAM2 may be located along the common electrode 173″, the second sub-dam SDAM2′, the outer side surfaces OS of the first sub-dam SDAM1′, the side surfaces 153 of the first planarization layer 150, and a surface (an upper surface) of the second interlayer insulating film 142. When the first angle θ1 between each side surface 153 and the second surface 152 of the first planarization layer 150 is within the above range, each side surface 153 of the first planarization layer 150 may form a gentle slope to the surface (the upper surface) of the second interlayer insulating film 142, thereby facilitating deposition of the first encapsulating inorganic layer 191. Accordingly, this may facilitate the encapsulation of an organic insulating layer by the first encapsulating inorganic layer 191 and the second encapsulating inorganic layer 193, which, in turn, improves the reliability of the display device 10.

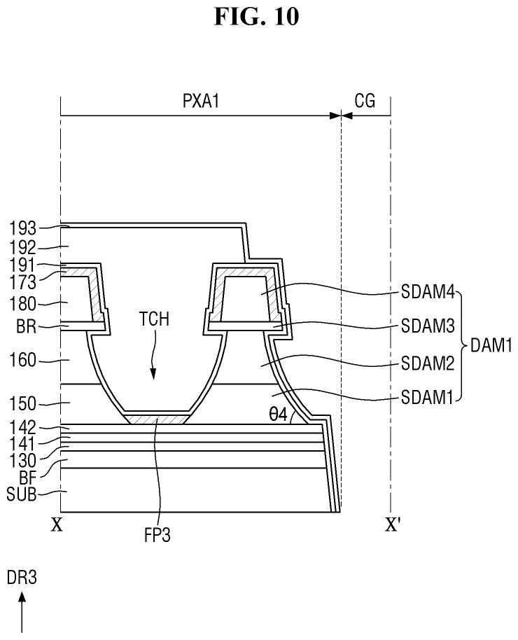

FIG. 10 is a cross-sectional view taken along line X-X′ of FIG. 6.

Referring to FIGS. 6 and 10, the first dam structure DAM1 may be located along the edges of the first pixel area PXA1. The first dam structure DAM1 may surround the first pixels PX1 located in the first pixel area PXA1. In other words, the first pixels PX1 may be located in an area surrounded by the first dam structure DAM1.

In the first pixel area PXA1, the first dam structure DAM1 may be located on the second interlayer insulating film 142. The first dam structure DAM1 may include a first sub-dam SDAM1 including the same material as the first planarization layer 150, a second sub-dam SDAM2 including the same material as the second planarization layer 160, a third sub-dam SDAM3 including the same material as the barrier layer BR, and a fourth sub-dam SDAM4 including the same material as the pixel defining layer 180. The first sub-dam SDAM1, the second sub-dam SDAM2, the third sub-dam SDAM3, and the fourth sub-dam SDAM4 may be sequentially stacked.

A groove TCH formed by removing the first planarization layer 150, the second planarization layer 160, and the barrier layer BR may be located inside the first dam structure DAM1. The first dam structure DAM1 may prevent the encapsulating organic layer 192 in the first pixel area PXA1 from overflowing to the outside of the display device 10. The groove TCH may expose the second interlayer insulating film 142. A dummy conductive layer FP3 may be located in the groove TCH of the first pixel area PXA1. The dummy conductive layer FP3 may include the same material as the common electrode 173.

The first sub-dam SDAM1 of the first dam structure DAM1 may include a first surface (an upper surface), a second surface (a lower surface), and side surfaces connecting the first surface and the second surface. The side surfaces of the first sub-dam SDAM1 may include inner side surfaces and outer side surfaces. The inner side surfaces may face the inside of the first pixel area PXA1, and the outer side surfaces may face the outside of the display device 10. In this case, a fourth angle θ4 formed by the second surface and each outer side surface of the first sub-dam SDAM1 may be substantially equal to or greater than the first angle θ1.

When the fourth angle θ4 is within the above range, encapsulation of an organic insulating layer by the encapsulation layer ENL may be facilitated. Therefore, the reliability of the display device 10 can be improved.

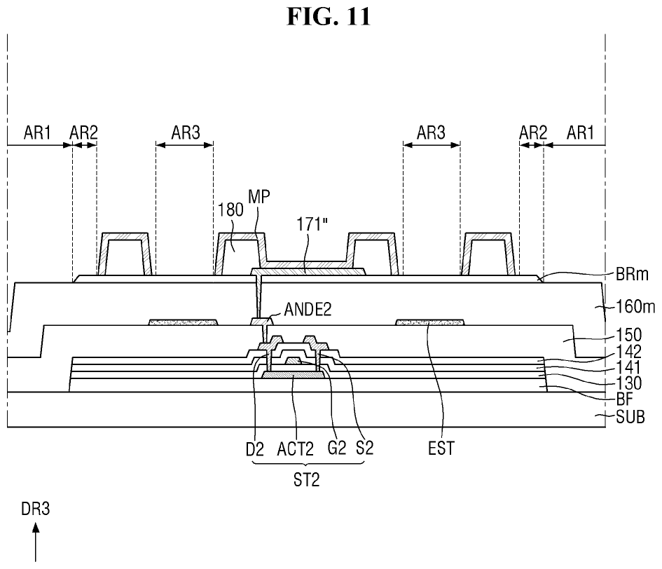

A method of manufacturing the display device 10 according to some embodiments will now be described with reference to FIGS. 11 through 14.

FIGS. 11 through 14 are cross-sectional views for explaining a method of manufacturing a display device 10 according to an embodiment. FIGS. 11 through 14 are cross-sectional views respectively illustrating processes for forming a second pixel area PXA2 of a display panel 100 according to an embodiment.

First, referring to FIG. 11, a second thin-film transistor ST2 is formed on a substrate SUB, and a first planarization layer 150 covering the second thin-film transistor ST2 is formed. Then, a second connection electrode ANDE2 and an etch stop pattern EST are formed on the first planarization layer 150, and a second planarization layer material layer 160m covering the second connection electrode ANDE2 and the etch stop pattern EST and a barrier material layer BRm located on the second planarization layer material layer 160m are formed. The etch stop pattern EST may include the same material as the second connection electrode ANDE2 and may be formed in the same process as the second connection electrode ANDE2. The etch stop pattern EST may be located at a position where a recess pattern RC is to be formed in order to prevent the first planarization layer 150 from being etched when the recess pattern RC is formed.

The barrier material layer BRm may be patterned to expose the second planarization layer material layer 160m in a first area AR1. In other words, a barrier material layer BRm is formed over the entire area of the substrate SUB. Then, the barrier material layer BRm located in the first area AR1 is etched, but the barrier material layer BRm located in the other area is not intentionally etched to pattern the barrier material layer BRm.

Next, a pixel electrode 171″ is formed on the barrier material layer BRm. The pixel electrode 171″ may be connected to the second connection electrode ANDE2 through a contact hole passing through the second planarization layer material layer 160m and the barrier material layer BRm.

Next, a pixel defining layer 180 covering edges of the pixel electrode 171″ is formed. The pixel defining layer 180 may be located on the contact hole passing through the second planarization layer material layer 160m and the barrier material layer BRm. The pixel defining layer 180 may expose a part of the pixel electrode 171″. A third sub-dam SDAM3′ may also be formed in the process of forming the pixel defining layer 180.

Next, a mask pattern MP is formed on the pixel electrode 171″ and the pixel defining layer 180. The mask pattern MP may be located not to cover the barrier material layer BRm in a second area AR2 and a third area AR3. The barrier material layer BRm may be exposed without being covered by the mask pattern MP. That is, the mask pattern MP may be located in the remaining area other than the first area AR1, the second area AR2, and the third area AR3. The second area AR2 may be located adjacent to the first area AR1 and may expose a first surface (an upper surface) and side surfaces of the barrier material layer BRm. The third area AR3 may be separated from the first area AR1 and the second area AR2 and may expose the first surface (the upper surface) of the barrier material layer BRm. The first area AR1, the second area AR2, and the third area AR3 may not overlap each other. The etch stop pattern EST may be located in the third area AR3.

As will be described later, the first area AR1 may correspond to an area in which cut parts CG (see FIG. 8) are located, and the third area AR3 may correspond to an area in which the recess pattern RC (see FIG. 8) is located. The first area AR1 is an area etched away from the second planarization layer material layer 160m or the pixel defining layer 180 to the substrate SUB. In the first area AR1, a thin-film transistor and other wirings may not be located, and only an insulating layer and a planarization layer may be located.

The mask pattern MP may include at least any one of a transparent conductive oxide (TCO) and an inorganic layer. For example, the transparent conductive oxide (TCO) may include at least any one of indium tin oxide (ITO) and indium zinc oxide (IZO), and the inorganic layer may include aluminum (Al), although the present disclosure is not limited thereto.

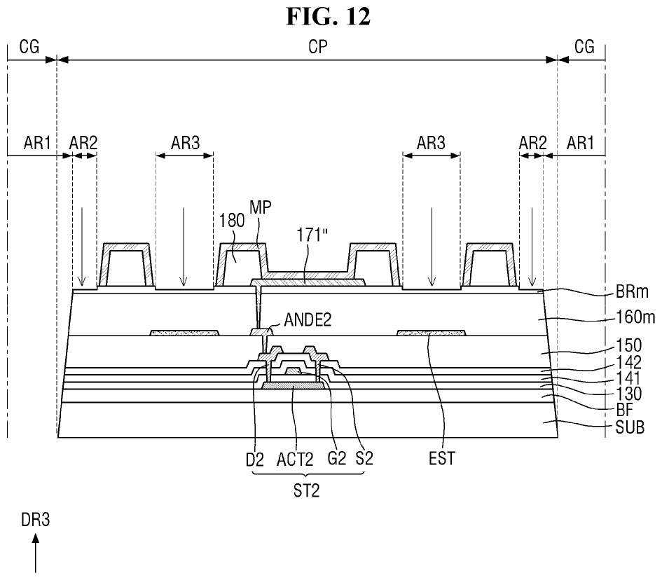

Next, referring to FIG. 12, the first area AR1 in which the mask pattern MP is not located is etched using the mask pattern MP.

For example, the first area AR1 is etched using the mask pattern MP as an etch mask. Accordingly, in the first area AR1, the second planarization layer material layer 160m, the first planarization layer 150, and the substrate SUB are etched. In the first area AR1, a second interlayer insulating film 142, a first interlayer insulating film 141, a gate insulating layer 130, and a buffer layer BF may not be located. Accordingly, the cut parts CG may be formed in the first area AR1, and a protruding pattern CP defined by the cut parts CG may be formed in the other area.

The process of forming the cut parts CG by etching the first area AR1 may be performed by anisotropic etching. When the process of forming the cut parts CG is performed by anisotropic etching, the anisotropic etching may include dry etching. In this case, an etching gas used in the dry etching may include, but is not limited to, Cl₂ or O₂.

In the etching for forming the cut parts CG, an upper part of the barrier material layer BRm of the second area AR2 and the third area AR3 may also be etched. In other words, a thickness of the barrier material layer BRm of the second area AR2 and the third area AR3 may be reduced by the etching.

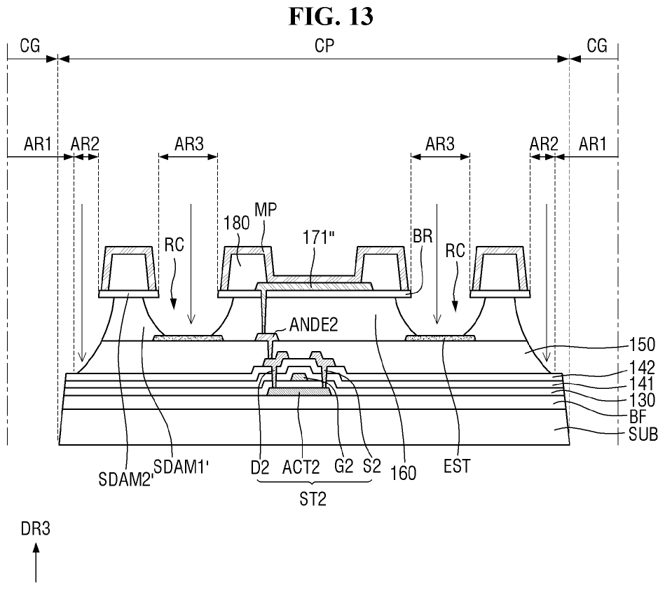

Next, referring to FIG. 13, the second area AR2 and the third area AR3 in which the mask pattern MP is not located are etched using the mask pattern MP.

For example, the second area AR2 and the third area AR3 are etched using the mask pattern MP as an etch mask. Accordingly, the barrier material layer BRm, the second planarization layer material layer 160m and the first planarization layer 150 are etched in the second area AR2, and the barrier material layer BRm and the second planarization layer material layer 160m are etched in the third area AR3. Because the etch stop pattern EST is located in the third area AR3, the first planarization layer 150 is not etched in the third area AR3, and only the barrier material layer BRm and the second planarization layer material layer 160m are etched. Accordingly, the recess pattern RC may be formed in the third area AR3. In addition, the barrier material layer BRm (see FIG. 12) and the second planarization layer material layer 160m (see FIG. 12) may be etched to form a barrier layer BR, a second planarization layer 160, a second sub-dam SDAM2′, and a first sub-dam SDAM1′. In this case, the outside of the first planarization layer 150 may also be etched.

The process of forming the recess pattern RC by etching the second area AR2 and the third area AR3 may be performed by isotropic etching. When the process of forming the recess pattern RC is performed by isotropic etching, the isotropic etching may include dry etching. In this case, an etching gas used in the isotropic etching may include, but is not limited to, CF4. In this case, the outside of the first planarization layer 150 may also be etched, and each side surface 153 (see FIG. 9) of the first planarization 150 may form a gentle slope.

For example, when the process of forming the recess pattern RC is performed by isotropic etching, side surfaces 163 (see FIG. 9) of the second planarization layer 160 and inner side surfaces IS (see FIG. 9) of the first sub-dam SDAM1′ which define side surfaces of the recess pattern RC may be formed to have a gentle slope.

In addition, because the barrier material layer BRm (see FIG. 12) is located in the second area AR2 and the third area AR3 and exposed by the mask pattern MP according to the process of FIG. 12, the isotropic etching may be performed in substantially the same manner in the second area AR2 and the third area AR3. Therefore, outer side surfaces OS (see FIG. 9) of the first sub-dam SDAM1′ and the side surfaces 153 (see FIG. 9) of the first planarization layer 150 may be formed by substantially the same process as the inner side surfaces IS (see FIG. 9) of the first sub-dam SDAM1′, and the side surfaces 153 (see FIG. 9) of the first planarization layer 150 may be formed to have a gentle slope.

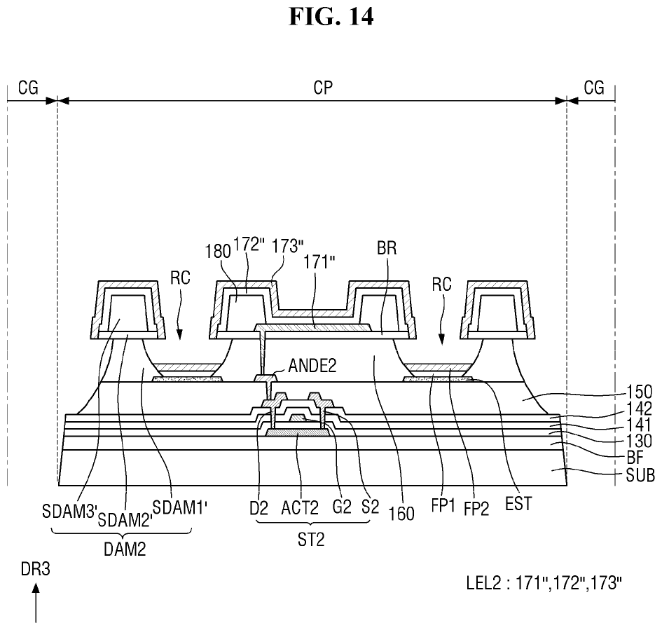

Next, referring to FIG. 14, the mask pattern MP is removed, and an organic layer 172″ and a common electrode 173″ are formed.

The organic layer 172″ may be located on the pixel defining layer 180 and the pixel electrode 171″. In this process, a dummy organic layer FP1 may be located in the recess pattern RC. The common electrode 173″ may be located on the organic layer 172″. In this process, a dummy common electrode layer FP2 may be located in the recess pattern RC.

The method of forming the second dam structure DAM2 and the recess pattern RC located on the protruding pattern CP has been described above, but the same description of the method of forming the second dam structure DAM2 may also be applied to a method of forming a first dam structure DAM1.

Hereinafter, other embodiments will be described. In the following embodiments, a description of the same elements as those of the above-described embodiments will be omitted or given briefly, and differences will be mainly described.

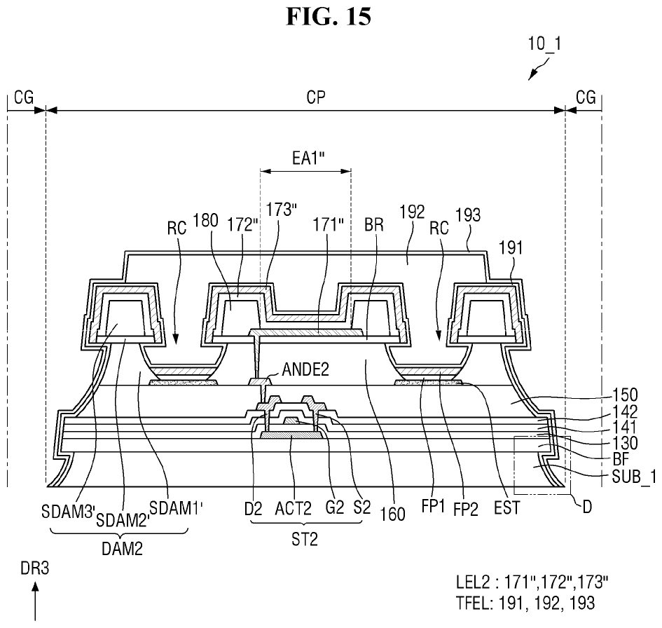

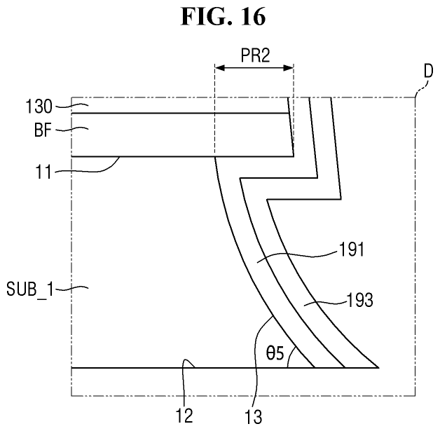

FIG. 15 is a cross-sectional view of a display device 10_1 according to an embodiment. FIG. 16 is an enlarged view of area D of FIG. 15. FIG. 15 illustrates a cross section of a protruding pattern CP of the display device 10_1 according to the embodiment.

Referring to FIGS. 15 and 16, the current embodiments are different from the embodiments of FIG. 8 in that side surfaces of a substrate SUB_1 of the display device 10_1 according to the current embodiments form a gentle curve.

For example, the substrate SUB_1 may include a first surface 11, a second surface 12, and side surfaces 13 connecting the first surface 11 and the second surface 12. The side surfaces 13 of the substrate SUB_1 may face the outside of the display device 10_1 or may face cut parts CG. When the side surfaces 13 of the substrate SUB_1 face the cut parts CG, they may face the side surfaces 13 of the substrates SUB_1 of adjacent protruding patterns CP. In addition, the cut parts CG may be defined by the side surfaces 13 of the substrate SUB_1.

A fifth angle θ5 formed by each side surface 13 and the second surface 12 of the substrate SUB_1 may be greater than a first angle θ1 (see FIG. 9), but the present disclosure is not limited thereto. In addition, the fifth angle θ5 may be greater than a fourth angle θ4 (see FIG. 10).

Side surfaces of a buffer layer BF may protrude further than the side surfaces 13 of the substrate SUB_1 by a second length PR2. In other words, each side surface of the buffer layer BF may protrude outward by the second length PR2 from a corner where the first surface 11 and a side surface 13 of the substrate SUB 1 meet. The second length PR2 may be smaller than a first length PR1 (see FIG. 9).

In the manufacturing method of FIGS. 11 through 14, the side surfaces 13 of the substrate SUB_1 according to the current embodiments may be formed while side surfaces 153 of a first planarization layer 150 are formed. However, the side surfaces 13 of the substrate SUB_1 may be etched for a shorter time than the time during which the side surfaces 153 of the first planarization layer 150 are etched. Accordingly, the fifth angle θ5 may be greater than the fourth angle θ4 (see FIG. 10), and the second length PR2 may be smaller than the first length PR1 (see FIG. 9).

Even in this case, because each side surface 153 of the first planarization layer 150 forms a gentle slope to a surface (an upper surface) of a second interlayer insulating film 142, encapsulation of an organic insulating layer by a first encapsulating inorganic layer 191 and a second encapsulating inorganic layer 193 may be facilitated. Therefore, the reliability of the display device 10_1 can be improved.

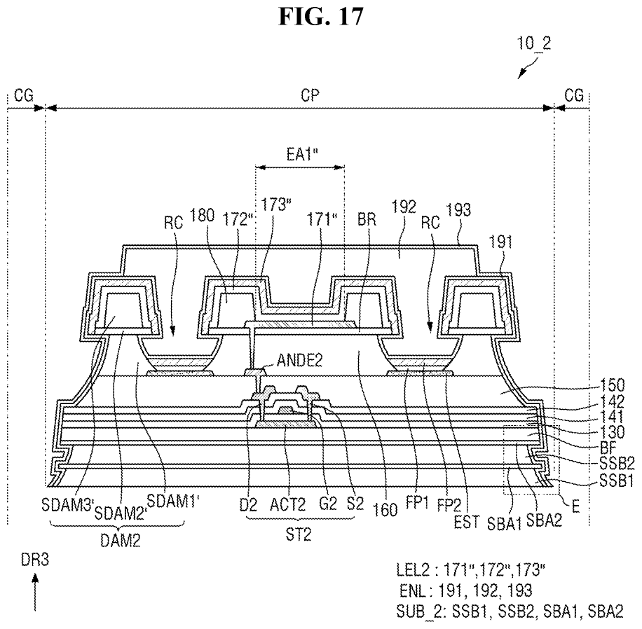

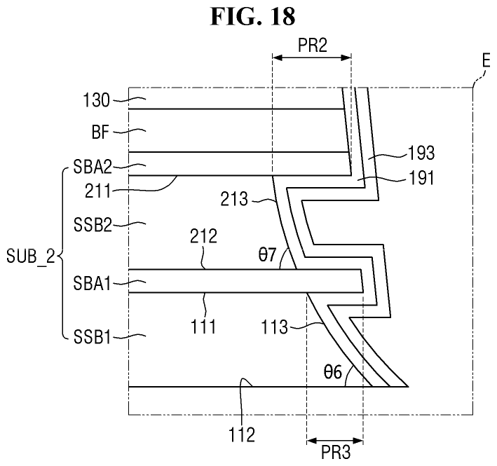

FIG. 17 is a cross-sectional view of a display device 10_2 according to an embodiment. FIG. 18 is an enlarged view of area E of FIG. 17. FIG. 17 illustrates a cross section of a protruding pattern CP of the display device 10_2 according to the embodiment.

Referring to FIGS. 17 and 18, the current embodiments is different from the embodiments of FIGS. 15 and 16 in that a substrate SUB_2 of the display device 10_2 according to the current embodiments includes a first sub-substrate SSB1, a first substrate barrier layer SBA1, a second sub-substrate SSB2, and a second substrate barrier layer SBA2.

For example, the first sub-substrate SSB1, the first substrate barrier layer SBA1, the second sub-substrate SSB2, and the second substrate barrier layer SBA2 may be sequentially located. The first sub-substrate SSB1 and the second sub-substrate SSB2 may be substantially the same as the substrate SUB (see FIG. 8). The first substrate barrier layer SBA1 and the second substrate barrier layer SBA2 may prevent diffusion of impurity ions, prevent penetration of moisture or outside air, and perform a surface planarization function. In addition, the first substrate barrier layer SBA1 and the second substrate barrier layer SBA2 may strengthen the adhesion between the first sub-substrate SSB1 and the second sub-substrate SSB2. The first substrate barrier layer SBA1 and the second substrate barrier layer SBA2 may include, but are not limited to, an inorganic material.

The first sub-substrate SSB1 may include a first surface 111, a second surface 112, and side surfaces 113 connecting the first surface 111 and the second surface 112. The second sub-substrate SSB2 may include a first surface 211, a second surface 212, and side surfaces 213 connecting the first surface 211 and the second surface 212.

A sixth angle θ6 formed by each side surface 113 and the second surface 112 of the first sub-substrate SSB1 may be greater than a seventh angle θ7 formed by each side surface 213 and the second surface 212 of the second sub-substrate SSB2. The seventh angle θ7 may be greater than a first angle θ1 (see FIG. 9).

Side surfaces of the first substrate barrier layer SBA1 may protrude further than the side surfaces 113 of the first sub-substrate SSB1 by a third length PR3. In other words, each side surface of the first substrate barrier layer SBA1 may protrude outward by the third length PR3 from a corner where the first surface 111 and a side surface 113 of the first sub-substrate SSB1 meet. As in FIGS. 17 and 18, side surfaces of the second sub-substrate SSB2 may protrude further than the side surfaces 213 of the second sub-substrate SSB2 by a second length PR2. The third length PR3 may be smaller than the second length PR2.

Even in this case, because each side surface 153 of a first planarization layer 150 forms a gentle slope to a surface (an upper surface) of a second interlayer insulating film 142, encapsulation of an organic insulating layer by a first encapsulating inorganic layer 191 and a second encapsulating inorganic layer 193 may be facilitated. Therefore, the reliability of the display device 10_2 can be improved.

According to a display device according to some embodiments, the reliability of the display device can be improved.

However, the effects of embodiments according to the present disclosure are not restricted to the ones set forth herein. The above and other effects of embodiments according to the present disclosure will become more apparent to one of daily skill in the art to which the present disclosure pertains by referencing the claims.

Although aspects of some embodiments of the present invention have been disclosed for illustrative purposes, those skilled in the art will appreciate that various modifications, additions and substitutions are possible, without departing from the scope and spirit of the invention as disclosed in the accompanying claims and their equivalents.

What is claimed is:

1. A display device comprising:
a substrate having a base and a protruding pattern protruding from the base;
a first planarization layer on the protruding pattern and comprising a first surface, a second surface, and side surfaces connecting the first surface and the second surface; and
a dam structure on the first planarization layer and comprises a first sub-dam and a second sub-dam,
wherein a first angle formed by the second surface of the first planarization layer and each of the side surfaces of the first planarization layer is in a range of 30 to 60 degrees.

2. The display device of claim 1, wherein the first sub-dam comprises a first surface, a second surface, inner side surfaces connecting the first surface of the first sub-dam and the second surface of the first sub-dam and facing the inside of the protruding pattern, and outer side surfaces connecting the first surface of the first sub-dam and the second surface of the first sub-dam and facing the outside of the protruding pattern, wherein a second angle formed by the second surface of the first sub-dam and each of the inner side surfaces of the first sub-dam is in the range of 30 to 60 degrees.

3. The display device of claim 2, wherein the first angle and the second angle are the same.

4. The display device of claim 1, further comprising:
a second planarization layer on the first planarization layer;
a barrier layer on the second planarization layer; and
a recess pattern defined by side surfaces of the second planarization layer and side surfaces of the first sub-dam of the dam structure,
wherein the side surfaces of the first sub-dam face the side surfaces of the second planarization layer.

5. The display device of claim 4, further comprising an etch stop pattern between the first planarization layer and the second planarization layer and exposed by the recess pattern.

6. The display device of claim 4, wherein the first sub-dam of the dam structure comprises a same material as the second planarization layer, and the second sub-dam of the dam structure comprises a same material as the barrier layer.

7. The display device of claim 4, further comprising:
a pixel electrode on the barrier layer;
an organic layer on the pixel electrode; and
a dummy organic layer in the recess pattern,
wherein the dummy organic layer comprises a same material as the organic layer and is separated from the organic layer.

8. The display device of claim 1, wherein the substrate comprises a first surface, a second surface, and side surfaces connecting the first surface of the substrate and the second surface of the substrate, wherein a third angle formed by the second surface of the substrate and each of the side surfaces of the substrate is greater than the first angle.

9. The display device of claim 8, further comprising a buffer layer between the substrate and the first planarization layer,
wherein each side surface of the second sub-dam of the dam structure protrudes outward by a first distance from a corner where a first surface of the first sub-dam meets a side surface of the first sub-dam,
wherein each side surface of the buffer layer protrudes outward by a second distance from a corner where the first surface of the substrate meets the side surface of the substrate, and
wherein the first distance is greater than the second distance.

10. The display device of claim 1, wherein the substrate further comprises a first sub-substrate, a substrate barrier layer on the first sub-substrate, and a second sub-substrate on the substrate barrier layer,
wherein the first sub-substrate comprises a first surface, a second surface and side surfaces connecting the first surface of the first sub-substrate and the second surface of the first sub-substrate,
wherein the second sub-substrate comprises a first surface, a second surface and side surfaces connecting the first surface of the second sub-substrate and the second surface of the second sub-substrate,
wherein a fourth angle formed by the second surface of the first sub-substrate and each of the side surfaces of the first sub-substrate is greater than a fifth angle formed by the second surface of the second sub-substrate and each of the side surfaces of the second sub-substrate.

11. The display device of claim 10, wherein the fourth angle and the fifth angle are greater than the first angle.

12. The display device of claim 1, further comprising:
a plurality of first pixels on the base; and
a plurality of second pixels on the protruding pattern.

13. The display device of claim 12, wherein the dam structure is arranged along edges of the protruding pattern and surrounds the second pixels.

14. A display device comprising:
a substrate which having a base and a protruding pattern protruding from the base;
a first planarization layer on the substrate and comprising a first surface, a second surface, and side surfaces connecting the first surface and the second surface;
a plurality of first pixels on the base; and
a plurality of second pixels on the protruding pattern,
wherein a first angle formed by the second surface of the first planarization layer and each of the side surfaces of the first planarization layer is in a range of 30 to 60 degrees.

15. The display device of claim 14, wherein the protruding pattern is provided in a plural,
wherein the first planarization layer is on each of a plurality of the protruding patterns, and
wherein the side surfaces of the first planarization layers on the protruding patterns face each other.

16. The display device of claim 14, further comprising a dam structure on the first planarization layer and surrounds the second pixels in a plan view.

17. A method of manufacturing a display device, the method comprising:
preparing a substrate, a first planarization layer on the substrate, a second planarization layer on the first planarization layer, a barrier material layer on the second planarization layer and exposing the second planarization layer in a first area, and a mask pattern on the barrier material layer and exposing the barrier material layer in a second area and a third area; and
forming a cut part by etching the second planarization layer, the first planarization layer, and the substrate in the first area,
wherein the second area exposes a first surface and side surfaces of the barrier material layer, and the third area exposes the first surface of the barrier material layer.

18. The method of claim 17, further comprising, after the etching of the first area, etching the barrier material layer, the second planarization layer and the first planarization layer in the second area and etching the barrier material layer and the second planarization layer in the third area.

19. The method of claim 18, wherein the etching of the first area is performed by anisotropic etching, and the etching of the second area and the third area is performed by isotropic etching.

20. The method of claim 19, wherein the first planarization layer etched in the second area comprises a first surface, a second surface, and side surfaces connecting the first surface and the second surface, wherein a first angle formed by the second surface of the first planarization layer and each of the side surface of the first planarization layer is in a range of 30 to 60 degrees.
